(19) United States
(12) Patent Application Publication
(10) Pub. No.: US 2005/0189960 A1
(43) Pub. Date: Sep. 1, 2005

(54) Method for testing a thin film transistor array

(75) Inventor: Kayoko Tajima, Tokyo (JP)

Correspondence Address: Paul D. Greeley, Esq.;Ohlandt, Greeley, Ruggiero & Perle, L.L.P., 10th Floor, One Landmark Square, Stamford, CT, 06901-2682, US

(73) Assignee: Agilent Technologies, Inc.

(21) Appl. No.: 11/003,165

(22) Filed: Dec. 3, 2004

(30) Foreign Application Priority Data
Feb. 26, 2004 (JP) 2004-052043

(51) Int. Cl. G01R 31/00

(52) U.S. Cl. 324/770

(57) ABSTRACT

A method for testing a thin film transistor array having pixels comprised of a transistor for controlling current, a capacitor connected between the gate terminal and the source terminal of this transistor, a first switch connected between the gate terminal and the drain terminal of this transistor, and a second switch, one terminal of which is connected to the drain terminal of this transistor and that turns on and off in synchronization with this first switch, this testing method characterized in that it comprises a step wherein the first and second switches are turned on, a step wherein a first voltage is applied to the other terminal of the second switch, and a step wherein a second voltage is applied to the other terminal of this second switch, and the charge flowing through this first switch is measured.

### 1. FIELD OF THE INVENTION

The present invention relates to a method for testing a TFT array that drives EL elements, and in particular, to a method for testing a TFT array having current copy-type pixels.

### 2. DISCUSSION OF THE BACKGROUND ART

Attention has been focused in recent years on EL elements (electroluminescence elements) as display elements for flat panel displays. EL elements are self-emission-type elements; therefore, they are characterized in that their display color field is broad and their energy consumption is low when compared to display elements that use conventional liquid crystals.

The emission brightness of EL elements fluctuates with the drive current. Therefore, TFT arrays for driving EL elements differ from TFT arrays that are used in conventional voltage control-type liquid crystals in that a structure is necessary with which the current applied to the light-emitting element can be controlled (refer to JP Kokai [unexamined] 2004-4801 and JP Kokai [unexamined] 2003-323,152).

A current copy-type pixel structure is shown in FIG. 2. This is a pixel of a TFT array used to drive a typical EL element. Of electrodes 15 and 28 that connect an EL element 25 (the status of the TFT array here is unsealed), electrode 15 is grounded, while the other electrode 28 is connected to a transistor switch 23. The other terminal of transistor switch 23 is connected to the drain terminal of a drive transistor 22, which supplies the drive current of EL 25. A capacitor 24 is connected between the gate terminal and the source terminal of drive transistor 22. A drive power source 27 of EL element 25 is connected to the source element of drive transistor 22. In addition, a transistor switch 21 is connected between the gate terminal and the drain terminal of drive transistor 22, and a different transistor switch 20 is connected to the drain terminal. Transistor switches 20 and 23 are turned on and off by the same control line 12. The other terminal of transistor switch 20 is connected to a data line 10, and the data line is connected to a current source 26. Each of transistor switches 20, 21, and 23 is a P-channel FET and is turned on by application of −5 V (“on” voltage) and is turned off by bringing the voltage to 0 V (“off” voltage).

The operation of the pixel in FIG. 2 will now be described. First, switches 20 and 23 are turned on by applying voltage to control line 12 and switch 23 is turned off by bringing control line 16 to “off” voltage. Thus, the current supplied from power source 27 flows into current source 26 through drive transistor 22 and switch 20. Current I that flows at this time is specified by current source 26. Moreover, because switch 21 is on, capacitor 24 is charged. The potential V of capacitor 24 after charging is equal to the voltage V between the gate and the source when current I is flowing to drive transistor 22.

When capacitor 24 is completely charged, control line 12 is brought to the “off” voltage and switches 20 and 21 are turned off. Switch 21 is off; therefore, capacitor 24 maintains a potential difference V. Then voltage is applied to control line 16 and switch 23 is turned on. Thus, current flowing from power source 27 flows to the EL element 25 through drive transistor 22 and switch 23. The current flowing to the EL element 25 at this time is controlled by the voltage between the gate and the source of drive transistor 22. Capacitor 24 charged to the potential difference V is connected between the gate and the source of drive transistor 22; therefore, the voltage between the gate and the source becomes V. As previously mentioned, the current flowing through drive transistor 22 when the voltage between the gate and the source is V becomes I; as a result, the drive current flowing to the EL element 25 becomes current I.

Thus, drive transistor 22 in FIG. 2 is characterized in that the EL element 25 can be driven by current I specified by current source 26, even after the connection with current source 26 has been broken. Pixels having this type of characteristic are called current copy-type pixels. It should be noted that there is also an embodiment wherein a specific potential is realized without grounding electrode 15, as is given in the working example, but the operating theory is the same.

However, all elements of the pixel must be functioning correctly in order for this type of current copy-type pixel to operate correctly. Moreover, if there are defects, these defects must be specified. Therefore, a pixel testing method must be established during the processes involved in TFT array production.

The EL element 25 is also expensive and is difficult to re-use once it has been sealed in a panel with a TFT array. Therefore, it is preferred that the pixels of the TFT array be tested before sealing, that is, before connecting the EL element 25 to electrodes 15 and 28 of the TFT array. However, if the EL element 25 is in an unsealed state, there will be an open state between electrode 15 and electrode 28 and the circuit will not be closed. Therefore, there is a problem in that it will not be possible to conduct the test with current flowing as it does during practical use.

### SUMMARY OF THE INVENTION

A method for testing a thin film transistor array having pixels comprised of a transistor for controlling current, a capacitor connected between the gate terminal and the source terminal of this transistor, a first switch connected between the gate terminal and the drain terminal of this transistor, and a second switch, one terminal of which is connected to the drain terminal of this transistor and that turns on and off in synchronization with this first switch, this testing method characterized in that it comprises a step wherein the first and second switches are turned on, a step wherein a first voltage lower than the threshold voltage of the transistor is applied to the other terminal of the second switch, and a step wherein a second voltage that is lower than the threshold voltage of the transistor and is different from this first voltage is applied to the other terminal of this second switch, and the charge flowing through this first switch is measured.

A method for testing a thin film transistor array having pixels comprised of a transistor for controlling current, a capacitor connected between the gate terminal and the source terminal of this transistor, a first switch connected between the gate terminal and the drain terminal of this transistor, and a second switch, one terminal of which is connected to the drain terminal of this transistor and that turns on and off in synchronization with this first switch, this testing method characterized in that it comprises a step wherein the first and second switches are turned on, a step wherein a variable voltage source is connected to the other terminal of this second switch, and a step wherein the voltage of this variable voltage source is varied and the correlation between this voltage and the current flowing through this second switch is measured. It is also possible to vary the current from a variable current source rather than varying the voltage from a variable voltage source and to measure the correlation between the voltage of the other terminal of the second switch and the current flowing through the switch.

A method for testing a thin film transistor array having pixels comprised of an electrode for connecting an EL element, a transistor for controlling the current of this EL element, a capacitor connected between the gate terminal and the source terminal of this transistor, a first switch connected between the gate terminal and the drain terminal of this transistor, a second switch, one terminal of which is connected to the drain terminal of this transistor and that turns on and off in synchronization with this first switch, and a third switch connected between one terminal of the electrode and the drain terminal of this transistor, this testing method characterized in that it comprises a step wherein the first switch and the second switch are turned on, a step wherein the third switch is turned on, the potential of the other terminal of this electrode is varied, and the first charge flowing through this second switch is measured, a step wherein this third switch is turned off, the potential of the other terminal of this electrode is varied, and the second charge flowing through this second switch is measured, and a step wherein the first charge and the second charge are compared.

A method for testing a thin film transistor array having pixels comprised of a transistor for controlling current, a capacitor connected between the gate terminal and the source terminal of this transistor, a first switch connected between the gate terminal and the drain terminal of this transistor, and a second switch, one end terminal of which is connected to the drain terminal of this transistor and that turns on and off in synchronization with this first switch, this testing method characterized in that it comprises a step wherein the first and second switches are turned on, a step wherein a pre-determined current is applied to the other terminal of this second switch, a step wherein a pre-determined voltage is applied to the source terminal of this transistor, and a step wherein the current flowing to the source terminal of this transistor is measured.

The present invention makes it possible to check for defects in current copy-type pixels with the EL element in an unsealed state.

### BRIEF DESCRIPTION OF THE DRAWINGS

FIG. 1 is an explanatory drawing of a working example (Example 1) of the present invention.

FIG. 2 is a structural diagram of a typical current copy-type pixel.

FIG. 3 is an explanatory drawing of a working example (Example 2) of the present invention.

FIG. 4 is an explanatory drawing of a working example (Example 3) of the present invention.

FIG. 5 is an explanatory drawing of a working example (Example 4) of the present invention.

FIG. 6 is a diagram showing the testing method of the present invention and the corresponding structural elements that are the subject of the test.

### DETAILED DESCRIPTION OF THE PREFERRED EMBODIMENT

The testing method that is a preferred embodiment of the present invention will now be described in detail while referring to the drawings. The present testing method comprises four tests, which are described here. FIG. 6 shows the test areas where operation can be confirmed by each of the tests. It can be confirmed that there are no defective elements among all of the structural elements of the pixel of a TFT array when all of the tests have been conducted. However, there is the problem that the testing time is long if tests of all elements are conducted. The probability that defects will be found in each structural element of a pixel generally differs with each structural element, and greatly differs with the process involved in TFT array production. Therefore, it is not always necessary to test each element; both a shortening of the testing time and the detection of defective TFT arrays can be expected when tests are conducted only on those structural elements that are likely to have defects.

### EXAMPLE 1

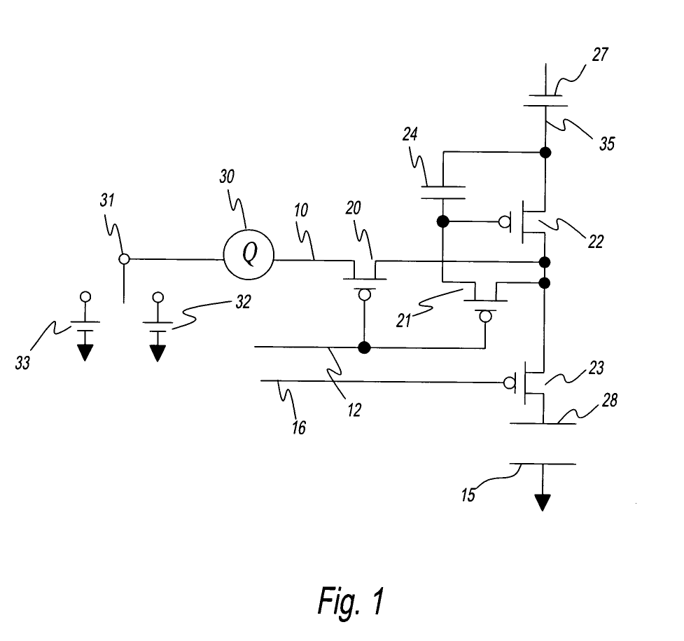

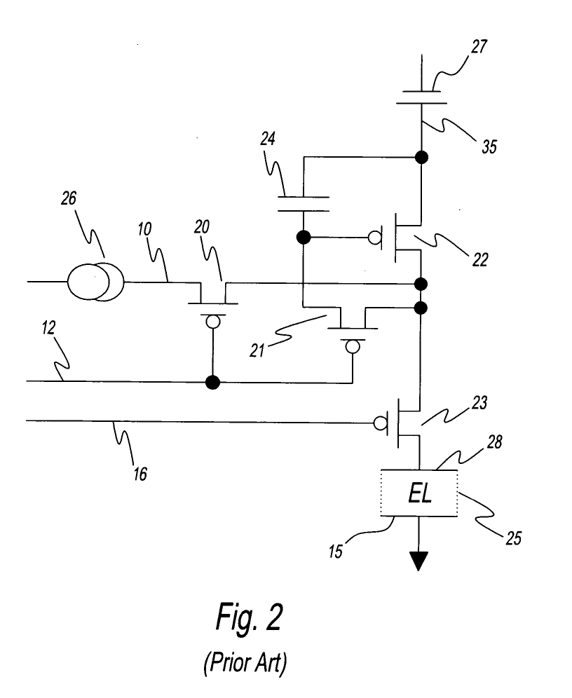

An example of a method for testing the pixels of a TFT array is shown in FIG. 1. This test tests the operation of switches 20 and 21 and a capacitor 24. A charge meter 30 is connected to a data line 10. The input terminal of a double-throw switch 31 is connected to the other terminal of charge meter 30. A power source 32 is connected to one output terminal of double-throw switch 31, while a power source 33 is connected to the other output terminal. The voltage V₁ of power source 32 and the voltage V₂ of power source 33 are different voltages. The voltage V₂ of power source 33 is set so that the potential difference from the voltage V₀ of power source 27 becomes the absolute value of the threshold voltage of a drive transistor 22 |V_{T}| or lower (|V_{T}|>|V₀−V₂|).

The testing method will now be described in detail. First, “on” voltage is applied to a control line 12 and switches 20 and 21 are turned on. A control line 16 is brought to “off” voltage and switch 23 is turned off. Moreover, the input terminal of switch 31 is connected to power source 32. As a result, the potential difference of capacitor 24 becomes V₀−V₁. When capacity of capacitor 24 is C in this case, capacitor 24 is charged to a charge Q₁=C (V₀−V₁).

Once the time needed for charging has passed, control line 12 is brought to “off” voltage and switch 31 is switched to power source 33. As a result, switch 20 is turned off; therefore, theoretically, current should not flow to data line 10. A very small offset current is present in actual TFT arrays; therefore, the current is not zero. Consequently, the offset current is first measured by charge meter 30 with switch 20 turned off.

Then “on” voltage is applied to control line 12 and switches 20 and 21 are turned on. As a result, the potential difference of capacitor 24 becomes V₀−V₂; therefore, the charge that accumulates in capacitor 24, Q₂ becomes C(V₀−V₂). The difference between Q₁ and Q₂, ΔQ=Q₁−Q₂=C(V₂−V₁), flows through data line 10 into power source 33. This difference in charge ΔQ is measured and the true difference is charge ΔQ′ is found by subtracting the charge created by the offset current from ΔQ. Finally, the capacitance C of capacitor 24=ΔQ′/(V₂−V₁) is found and the capacitance C is assessed as to whether or not it is within a pre-determined allowable range.

It should be noted that the operation of switch 23 can be confirmed by comparing the results when “on” voltage is applied to control line 16 to turn switch 23 on and performing the same measurement. That is, as long as switch 23 is operating correctly, the measurements when switch 23 is on and when it is off will be different due to the parasitic capacitance between the gate and the drain of transistor switch 23, or the parasitic capacitance between the data lines adjacent to the drain of transistor switch 23 and the control lines of other pixels. It is also possible to simultaneously confirm the operation of switch 23 by measuring this difference.

When there are defects in switches 20 and 21, capacitor 24 cannot be charged and certain symptoms will be displayed, including the flow of a large offset current; therefore, the operation of switches 20 and 21 can be simultaneously confirmed by this test.

### EXAMPLE 2

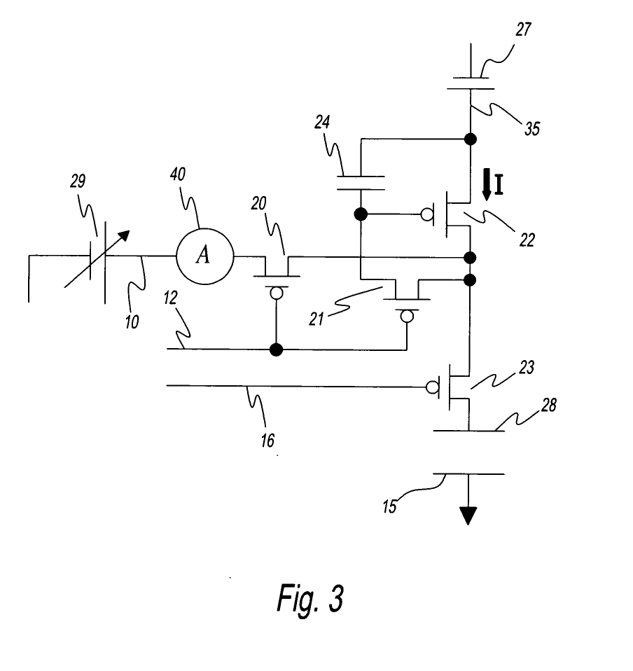

A different example of the method for testing pixels of a TFT array is shown in FIG. 3. This test tests the operation of switches 20 and 21 and drive transistor 22. By means of this test, a variable voltage source 29 and an ammeter 40 are connected to data line 10. Moreover, “on” voltage is applied to control line 12 and switches 20 and 21 are turned on. Control line 16 is brought to “off” voltage and switch 23 is turned off. Next, the voltage of variable voltage source 29 is varied and the current I of data line 10 is measured at every voltage V using ammeter 40. Transistor switch 20 is on; therefore, although there are differences due to a voltage drop created as a result of “on” resistance, the voltage V is virtually the same as the gate voltage of transistor 22. Moreover, the current I that flows to ammeter 40 is the current that flows from power source 27 through drive transistor 22 and switch 20. Therefore, this current is the same as the drive current of drive transistor 22. Thus, the correlation between the current I and the voltage V is virtually the same as the IV property of drive transistor 22. Therefore, it can be assessed from the measurement results whether or not drive transistor 22 has the desired properties.

When there are defects in switches 20 and 21, current will not flow to drive transistor 22, even when the voltage of the variable voltage source fluctuates; therefore, it is possible to simultaneously confirm the operation of switches 20 and 21 by this test. The IV property of transistor 22 can also be measured by connecting a variable current source in place of variable voltage source 29 of the present working example and a voltammeter in place of ammeter 40 and measuring the voltage V of the drain terminal of switch 20 while varying the current I of the variable current source.

### EXAMPLE 3

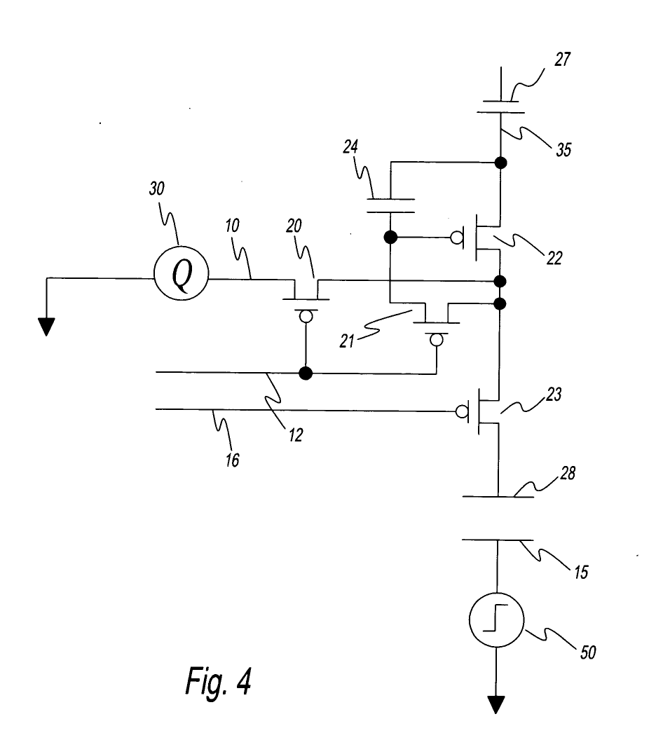

FIG. 4 shows yet another example of the method for testing pixels of TFT arrays. This test tests the operation of switches 20 and 23. A signal generator 50 is connected to electrode 15 and a charge meter 30 is connected to data line 10. “On” voltage is applied to control line 12 in this state and switch 20 is turned on.

First, “on” voltage is applied to control line 16 and switch 23 is turned on. Signal generator 50 gives step signals to electrode 15. Electrode 15 and electrode 28 function as capacitors because the EL element is in an unsealed state. Therefore, a current with a very fine waveshape from the step signals flows to data line 10 through switches 23 and 20. Charge Q₁ that flows at this time is measured by charge meter 30. Next, once control line 16 is brought to “off” voltage and the switch is turned off, step signals are applied to electrode 15, and charge Q₂ that flows to data line 10 is measured with charge meter 30. If switch 23 is operating correctly, current will not flow to data line 10 when switch 23 is off; therefore, charge Q₁ and charge Q₂ will be different values. Thus, the operation of switch 23 can be confirmed by finding the difference ΔQ=Q₁−Q₂ between the two charges.

Here, the method is used here whereby when the offset current flowing to data line 10 is large, the offset current flowing to data line 10 is pre-measured, the charge from the offset current is calculated, and the true charge is found by subtracting the charge from the offset current from the pre-measured offset current. The present test can also be conducted after pre-measuring the offset current and then connecting to data line 10 a constant-current source with the same current as the offset current but wherein the flow of the current is the opposite of the offset current in order to cancel the offset current.

The output waveshape of signal generator 50 is not limited to step signals and can be pulse signals, triangular wave signals, sine wave signals, or other signals with which voltage changes over time. Furthermore, signal generator 50 is not necessarily connected to electrode 15; it can be connected to an adjacent data line or control line of another pixel, and the like. In this case, the charge that is measured is the charge from the current flowing to the parasitic capacitance between the line that connects signal generator 50 and electrode 28.

When there are defects in switch 20, the charge flowing to charge meter 30 will not change when switch 23 is turned on and off in this test. Therefore, it is possible to simultaneously check switch 20 for defects.

In addition to this testing method, the method whereby control line 16 is changed from “off” voltage to “on” potential and the charge that flows into charge meter 30 is measured is a method for confirming the operation of switch 23. The measurements that are obtained when switch 23 turns on correctly and when there are defects and the switch does not turn on differ by the parasitic capacitance between the gate and the drain of transistor switch 23 and the parasitic capacitance between the drain terminal of transistor switch 23 and adjacent data lines or control lines of other pixels; therefore, the operation of transistor 23 can be confirmed by measuring this difference. By means of this method, capacitor 24 is not charged to the parasitic capacitance of transistor switch 23 using signal generator 50. As shown by the circuit in FIG. 1, capacitor 24 is charged to the parasitic capacitance of transistor switch 23 by current from power source 27. In this case, the time it takes to find the true charge by subtracting the offset current from the measurement results can be saved by pre-measuring the offset current and connecting to data line 10 a constant current source with the same current as the offset current but the opposite current direction from the offset current in order to cancel the offset current.

### EXAMPLE 4

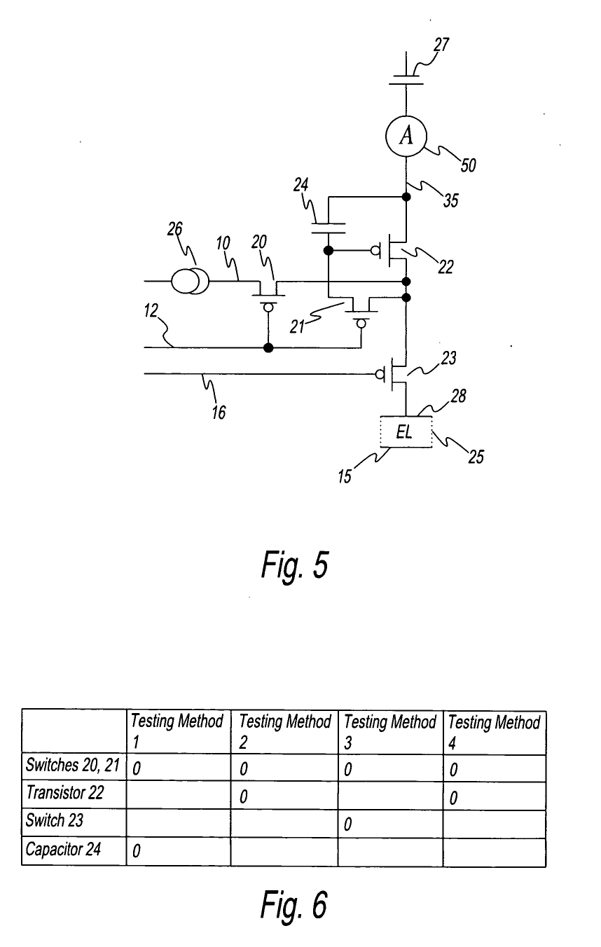

Still another example of the method for testing pixels of a TFT array is shown in FIG. 5. This test tests the operation of switches 20 and 21 and drive transistor 22. By means of this text, an ammeter 50 is placed between electrode 27 and the source terminal of drive transistor 22. Moreover, “on” voltage is applied to control line 12 and switches 20 and 21 are turned on. If switches 20 and 21 and transistor 22 are operating correctly, the current at ammeter 50 should be the same as the current flowing to current source 26. On the other hand, if there are leaks or shorts somewhere, or if switch 20 or 21 or transistor 22 do not operate, the output from current source 26 will be different from the value of ammeter 50. It is possible to confirm the operation of switches 20 and 21 and transistor 22 by comparing the measurement of ammeter 50 and the current flowing to current source 26.

The technological concept relating to the present invention has been described in detail while referring to specific working examples, but it is clear that various changes and modifications can be made without deviating from the intention and scope of the claims. The primary subject of the present invention is to test before the EL element 25 is sealed, but the present invention can also be used to test a TFT panel once EL element 25 has been sealed inside. It should be noted that once the EL element 25 has been sealed inside, the circuit inside the pixel is a closed circuit; therefore, the drive current of the EL element 25 can be directly determined by setting up ammeter 50 as shown in FIG. 5.

1. A method for testing a thin film transistor array having pixels comprised of:
a transistor for controlling current, said transistor comprising a gate terminal, a source terminal and a drain terminal;
a capacitor connected between said gate terminal and said source terminal of said transistor;
a first switch connected between said gate terminal and said drain terminal of said transistor; and
a second switch comprising a terminal which is connected to said drain terminal of said transistor and that turns on and off in synchronization with said first switch,
said testing method comprising:
turning on said first and second switches;
applying a first voltage lower than a threshold voltage of said transistor to said terminal of said second switch; and
applying a second voltage that is lower than said threshold voltage of said transistor and which is different from said first voltage said terminal of said second switch, and measuring a charge flowing through said first switch.

2. A method for testing a thin film transistor array having pixels comprised of:
a transistor for controlling current, said transistor comprising a gate terminal, a source terminal and a drain terminal;
a capacitor connected between said gate terminal and said source terminal of said transistor;
a first switch connected between said gate terminal and said drain terminal of said transistor; and
a second switch comprising a terminal is connected to said drain terminal of said transistor and that turns on and off in synchronization with said first switch,
said testing method comprising:
turning on said first and second switches;
connecting a variable voltage source to said terminal of said second switch; and
varying a voltage of said variable voltage source and measuring a correlation between said voltage and a current flowing through said second switch.

3. A method for testing a thin film transistor array having pixels comprised of:
a transistor for controlling current, said transistor comprising a gate terminal, a source terminal and a drain terminal;
a capacitor connected between said gate terminal and said source terminal of said transistor;
a first switch connected between said gate terminal and said drain terminal of said transistor; and
a second switch comprising a terminal which is connected to said drain terminal of said transistor and that turns on and off in synchronization with said first switch,
said testing method comprising:
turning on said first and second switches;
connecting a variable current source to said terminal of said second switch; and
varying a current of said variable current source and measuring a correlation between said current and a voltage of said terminal of said second switch.

4. A method for testing a thin film transistor array having pixels comprised of
an electrode for connecting an electroluminescence element;
a transistor for controlling a current of said electroluminescence element, said transistor comprising a gate terminal, a source terminal and a drain terminal;
a capacitor connected between said gate terminal and said source terminal of said transistor;
a first switch connected between said gate terminal and said drain terminal of said transistor;
a second switch comprising a terminal which is connected to said drain terminal of said transistor and that turns on and off in synchronization with said first switch; and
a third switch connected between one terminal of said electrode and said drain terminal of said transistor,
said testing method comprising:
turning on said first switch and said second switch;
turning on said third switch, varying a potential of another terminal of said electrode, and measuring a first charge flowing through said second switch;
turning off said third switch, varying said potential of said other terminal of said electrode, and measuring a second charge flowing through said second switch; and
comparing said first charge and said second charge.

5. A method for testing a thin film transistor array having pixels comprised of:
a transistor for controlling current, said transistor comprising a gate terminal, a source terminal and a drain terminal;
a capacitor connected between said gate terminal and said source terminal of said transistor;
a first switch connected between said gate terminal and said drain terminal of said transistor; and
a second switch comprising a terminal which is connected to said drain terminal of said transistor and that turns on and off in synchronization with said first switch,
said testing method comprising:
turning on said first and second switches;
applying a predetermined current to said terminal of said second switch;
applying a predetermined voltage to said source terminal of said transistor; and
measuring a current flowing to said source terminal of said transistor.
